(19) United States
(12) Patent Application Publication
(10) Pub. No.: US 2011/0171833 A1
(43) Pub. Date: Jul. 14, 2011

(54) DRY ETCHING METHOD OF HIGH-K FILM

(76) Inventors: Koichi NAKAUNE, Hikari (JP); Masatoshi OYAMA, Kudamatsu (JP); Motohiro TANAKA, Kudamatsu (JP); Hitoshi TAMURA, Hikari (JP); Masamichi SAKAGUCHI, Kudamatsu (JP)

(21) Appl. No.: 13/072,904

(22) Filed: Mar. 28, 2011

Related U.S. Application Data
(63) Continuation of application No. 12/016,434, filed on Jan. 18, 2008.

(30) Foreign Application Priority Data
Sep. 7, 2007 (JP) 2007-232157

(51) Int. Cl. H01L 21/302

(52) U.S. Cl. 438/706; 257/E21.214

(57) ABSTRACT

An object of the invention is to provide a dry etching method of a metal oxide High-k film having etching characteristics which achieve a small etching rate difference and a small profile difference between open area and dense area while keeping a high selectivity to a polysilicon underlying film. In the method of dry-etching a High-k film by using a plasma, a small amount of fluorocarbon gas having a high carbon ratio is added to a BCl₃ gas mixed with a rare gas.

This application is a Continuation application of application Ser. No. 12/016,434, filed Jan. 18, 2008, the contents of which are incorporated herein by reference in their entirety.

### FIELD OF THE INVENTION

The present invention relates a dry etching method of a semiconductor surface and, more particular, to a dry etching method of a High-k film in manufacturing a semiconductor device.

### BACKGROUND OF THE INVENTION

In a recent semiconductor device, a metal oxide film having a high dielectric constant (to be referred to as a High-k film hereinafter) is used as a gate insulating film for attaining a miniaturization of a semiconductor device. In particular, in NAND Flash device, a High-k film made of Al₂O₃ (alumina), ZrO₂ (zirconia), HfO₂ (hafnium oxide), or the like is used as an insulating film between a control gate and a floating gate. These two gates each are made of polysilicon or the like. Furthermore, this device have isolation structure. When a High-k film is to be etched in manufacture of such a device, a step is formed by the floating gate and the isolation structure. For this reason, a high selectivity (ratio) to a polysilicon underlayer is needed.

In etching of a High-k film having low volatility of an Al₂O₃ film or the like, a gas containing Cl₂, BCl₃, or the like is generally used. As a conventional technique, for example, JP-A-2005-268292 discloses that a chlorine-based gas and a reducing gas such as CH₄ or the like are mixed with each other to execute etching.

### BRIEF SUMMARY OF THE INVENTION

A structure of a Flash device is configured as shown in FIG. 7. More specifically, an underlying insulating film (gate oxide film) 15 made of a silicon oxide film and a polysilicon film 14 are formed on a silicon substrate 17 made of a silicon oxide film. The silicon substrate 17 has an isolation trench 16 formed thereon. The polysilicon film 14 is patterned up to the isolation trench 16 and the underlying insulating film (gate oxide film) 15 and then etched to form a floating gate 14. After a High-k film 13 made of Al₂O₃ or the like and having a step 28 is formed on the floating gate 14, a polysilicon film 12 serving as a control gate and a tungsten silicide film 11 are formed, and a hard mask 10 is finally formed. Thereafter, patterning and etching processes are performed to form a Flash device on the underlying insulating film (gate oxide film) 15. In this case, the polysilicon film (control gate) 12 is formed to be orthogonal to the polysilicon film (floating gate) 14.

However, in the conventional technique, an addition of the gas having high reducibility increases not only an etching rate of the High-k film but also etching rates of a hard mask of a silicon oxide film and an isolation trench. Consequently, a selectivity to the silicon oxide film disadvantageously decreases.

In order to solve the above problem, it is an object of the present invention to provide a dry etching method of a High-k film having etching characteristics with a small etching rate difference and a small profile difference between open area and dense area of a pattern while keeping a high selectivity to a polysilicon underlying film in etching of a metal oxide serving as the High-k film.

In order to perform plasma etching to a metal oxide film made by bonding a metal and oxygen, a fluorocarbon-based gas having a high carbon ratio is added as an additive gas to a gas mixture of a rare gas and BCl₃ (boron trichloride). As a consequence, a High-k film can be etched at a high selectivity to an polysilicon underlayer without a difference in pattern density.

That is, the present invention provides a dry etching method of a High-k film, comprising the step of adding a fluorocarbon-based gas to a gas mixture of a rare gas and a BCl₃ gas in a plasma-etching of a metal oxide film made by bonding a metal and oxide.

Additionally, the present invention provides the above dry etching method wherein a metal constituting the metal oxide film includes at least one metal selected from the group consisting of Al, Hf, Zr, Ta and Si.

Additionally, the present invention provides the above dry etching method wherein the metal oxide film is constituted by a stacked film made of at least one selected from the group consisting of Al₂O₃, HfO₂, ZrO₂, AlHfO and Ta₂O₅.

Additionally, the present invention provides the above dry etching method wherein the fluorocarbon-based gas is a gas mixture containing at least one selected from the group consisting of C₂F₄, C₃F₈, C₄F₈, C₄F₆ and C₅F₈.

Additionally, the present invention provides the above dry etching method wherein the rare gas is a gas mixture containing at least one selected from the group consisting of He, Ne, Ar, Kr and Xe.

Additionally, the present invention provides the above dry etching method wherein, in the gas mixture, a flow-rate ratio of the fluorocarbon-based gas to the BCl₃ gas ranges from 2% to 5%.

Other objects, features and advantages of the invention will become apparent from the following description of the embodiments of the invention taken in conjunction with the accompanying drawings.

### BRIEF DESCRIPTION OF THE DRAWINGS

FIG. 1 is an overall block diagram of a plasma etching apparatus to which the present invention is applied.

FIGS. 2A to 2D are sectional views showing steps in manufacturing a gate electrode of NAND Flash memory according to an embodiment of the present invention.

FIGS. 3A and 3B are sectional views of etching profile changing depending on the presence/absence of an additive C₄F₈ gas.

FIGS. 4A to 4C are sectional views of etching profile of open pattern area and dense pattern area when the C₄F₈ gas is not added.

FIGS. 5A to 5C are sectional views of etching profile of open pattern area and dense pattern area when the C₄F₈ gas is added.

FIG. 6 is a graph showing a relationship of a loading effect of etching rates to a flow-rate ratio between BCl₃ and C₄F₈.

FIG. 7 is a sectional view for explaining a structure of a Flash device having a High-k film.

### DESCRIPTION OF REFERENCE NUMERALS

1 Magnetron
2 Waveguide tube
3 Quartz plate
4 Solenoide coil
5 Plasma
6 Wafer
7 DC power supply
8 Electrode
9 High-frequency power supply
10 Hard mask
11 Tungsten silicide film
12 Polysilicon film (control gate)
13 High-k film
14 Polysilicon film (floating gate)
15 Underlying insulating film (gate oxide film)
16 Isolation trench
17 Silicon substrate
18 Amount of remaining polysilicon film at dense area
19 Amount of remaining polysilicon film at open area
20 High-k film at dense area
21 High-k film at open area
22 Loading effect on amounts of remaining High-k film
23 Amount of etching isolation trench at dense area
24 Amount of etching isolation trench at open area
25 Loading effect on amounts of etching isolation trenches
26 Loading effect on amounts of remaining polysilicon film
27 Range where loading effect of etching rate is low
28 High-k step

### DETAILED DESCRIPTION OF THE INVENTION

An embodiment of the present invention is described below.

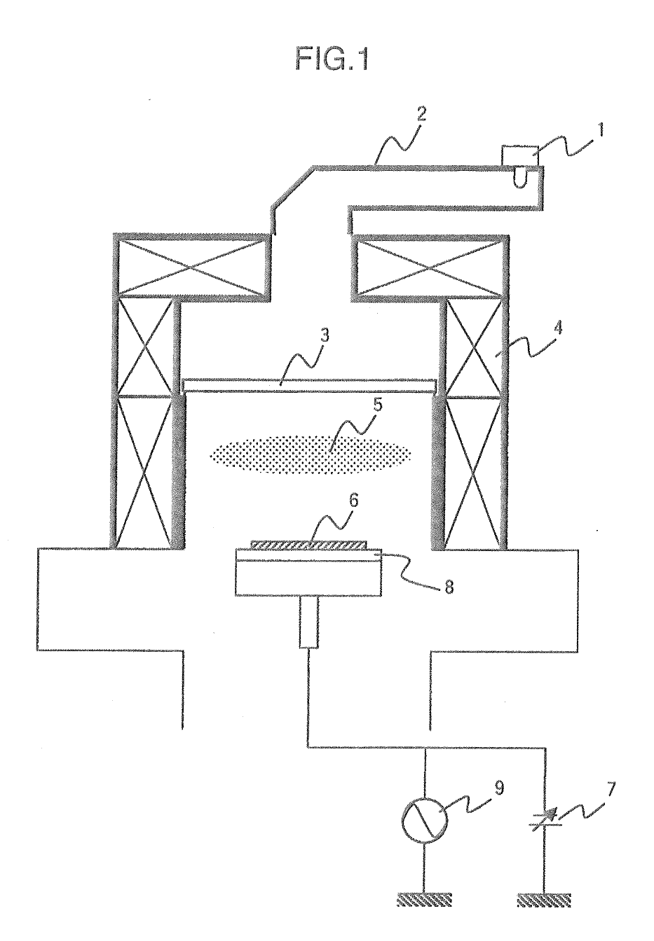

FIG. 1 shows a plasma etching apparatus used to carry out the present invention. The embodiment shows an exemplary microwave plasma etching apparatus using a microwave and a magnetic field in plasma generating means. In FIG. 1, the microwave is oscillated by a magnetron 1, passes through a waveguide tube 2, and is incident on a vacuum chamber through a quartz plate 3. A solenoide coil 4 is arranged around the vacuum chamber. A magnetic field generated by the solenoide coil 4 and the incident microwave cause electron cyclotron resonance (ECR). By this reaction, the process gas is efficiently made into a high-density plasma 5. A wafer 6 is fixed to an electrode by electrostatic adsorption such that an electrostatic adsorption power supply 7 applies a DC current voltage to electrode 8. A high-frequency power supply 9 is connected to the electrode. A high-frequency power is applied to the high-frequency power supply 9 to cause ions in a plasma to be incident by applying an acceleration potential perpendicular to the wafer 6, so that etching is performed. A gas obtained after the etching is discharged from a discharge port formed at a lower portion of the apparatus by a turbo pump and a dry pump (not shown).

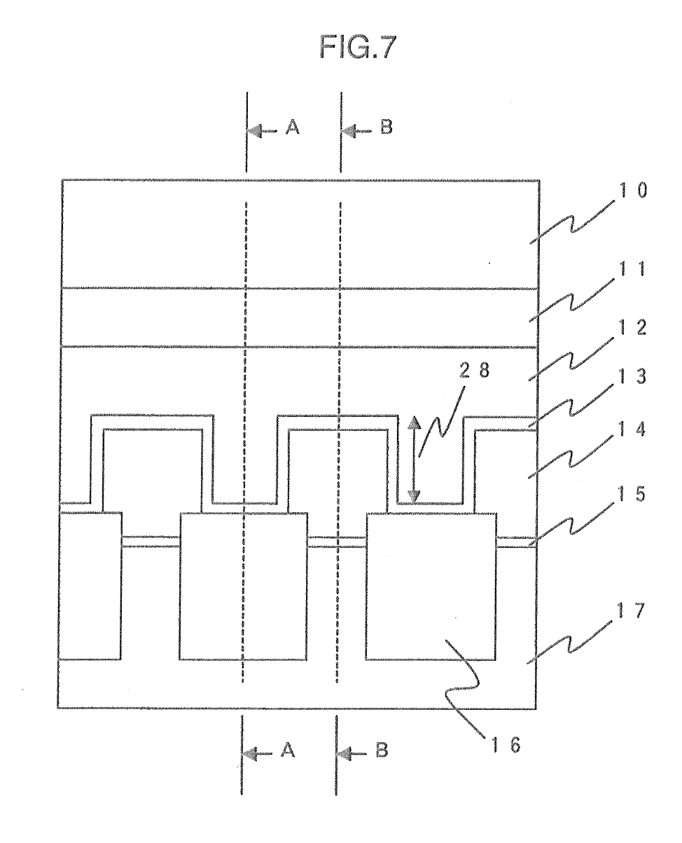

A wafer subjected to an etching process according to the present invention is a wafer shown in FIG. 7. From the top, a stacked film constituted by a patterned hard mask 10, a tungsten silicide film 11 serving as a control gate, and a polysilicon film 12, an interlayer insulating film 13 made of Al₂O₃, a polysilicon film 14 serving as a floating gate, an underlying insulating film (gate oxide film) 15 constituted by a silicon oxide film, and a silicon substrate 17 in which an isolation trench 16 buried with a silicon oxide film is formed.

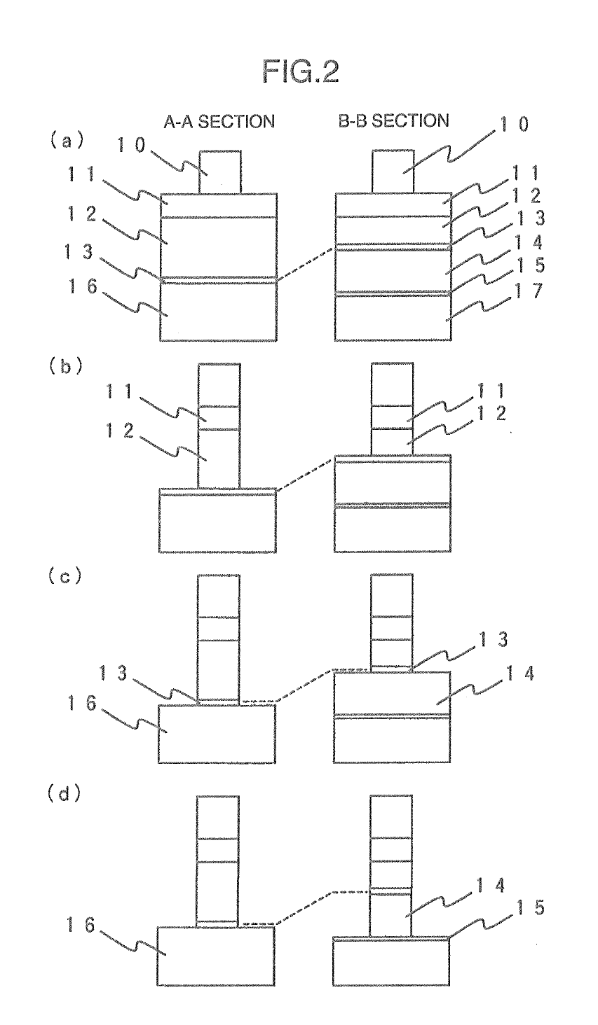

A method of manufacturing a semiconductor device according to the present invention will be described below with reference to FIGS. 2A to 2D. Left views in FIGS. 2A to 2D are explanatory views of FIG. 7 along an A-A section, and right views in FIGS. 2A to 2D are explanatory views of FIG. 7 along a B-B section.

Using the plasma etching apparatus shown in FIG. 1, the tungsten silicide film 11 is etched by a gas mixture of Cl₂ and CF₄ and the underlying polysilicon film 12 is etched by a gas mixture of HBr and O₂ by using as a mask the hard mask 10 constituted by the patterned silicon oxide film (FIG. 2B).

The High-k film Al₂O₃ serving as an interlayer insulating film is etched by using a gas mixture of Ar, BCl₃, and C₄F₈ (FIG. 2C). At this time, Al₂O₃ etching having a high selectivity to the polysilicon 14 serving as an underlying film of Al₂O₃ is necessary. A high selectivity to the isolation trench 16 constituted by a silicon oxide film serving as the other underlying film is desired.

Furthermore, the polysilicon film 14 constituting a floating gate is etched by a gas mixture of Cl₂, HBr, and O₂. Thereafter, overetching is performed by a gas mixture of HBr and O₂.

In the present invention, in processing for the High-k film 13 shown in FIG. 2C, a small amount of C₄F₈ of a fluorocarbon-based gas is added. An effect of adding C₄F₈ is described below.

As shown in FIG. 7, the High-k film 13 serving as an interlayer insulating film has a step 28 and is formed on the polysilicon film 14 and the isolation trench 16. The High-k step 28 is completely removed. At this time, when an amount of remaining film of the polysilicon film 14 is small, the underlying insulating film (gate oxide film) 15 is eliminated during the etching of the polysilicon film, a punch through phenomenon which damages the silicon substrate 17 occurs to considerably deteriorate device performance.

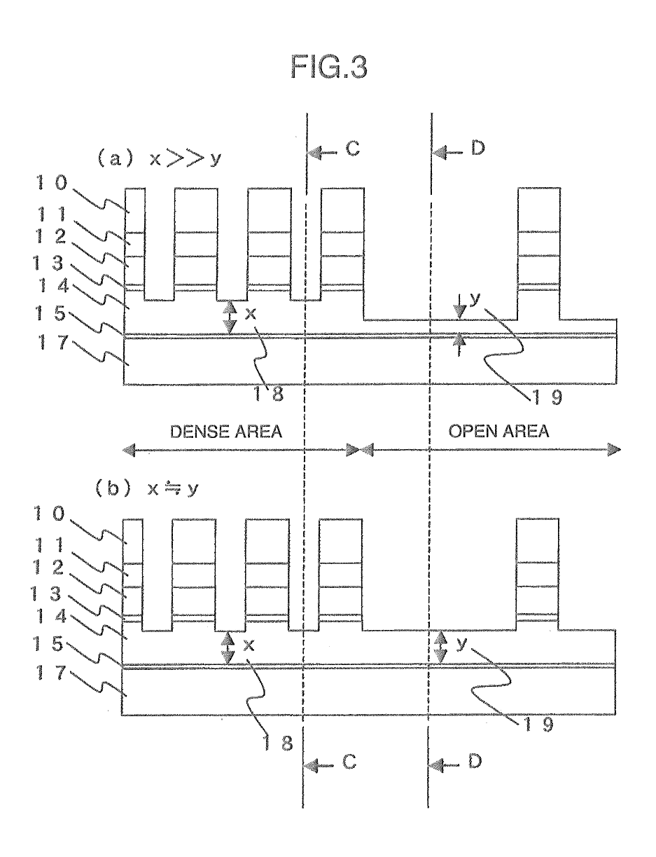

FIG. 3B is a view showing a B-B sectional shape in FIG. 7 at dense area where a pattern of a control gate is dense and open area where the pattern of the control gate is thin when Ar, BCl₃, and C₄F₈ gas flow rates are set at 60, 60, and 2 ccm, respective, and the High-k film is completely removed at a pressure of 3 mTorr in a vacuum chamber, a microwave power of 1400 W, and a high-frequency power of 70 W.

In this case, amounts of remaining polysilicon at the dense pattern area and the open pattern area are almost equal to each other (x≈y) due to the adding effect of the C₄F₈ gas. However, when the C₄F₈ gas is not added, an etching rate of the polysilicon at open area is larger than that at dense area. For this reason, as shown in FIG. 3A, a difference in pattern density between the amount of remaining polysilicon becomes very large as shown in FIG. 3A (x>>y), and a punch through phenomenon, in which an underlying insulating film (gate oxide film) has gone, occurs at open area.

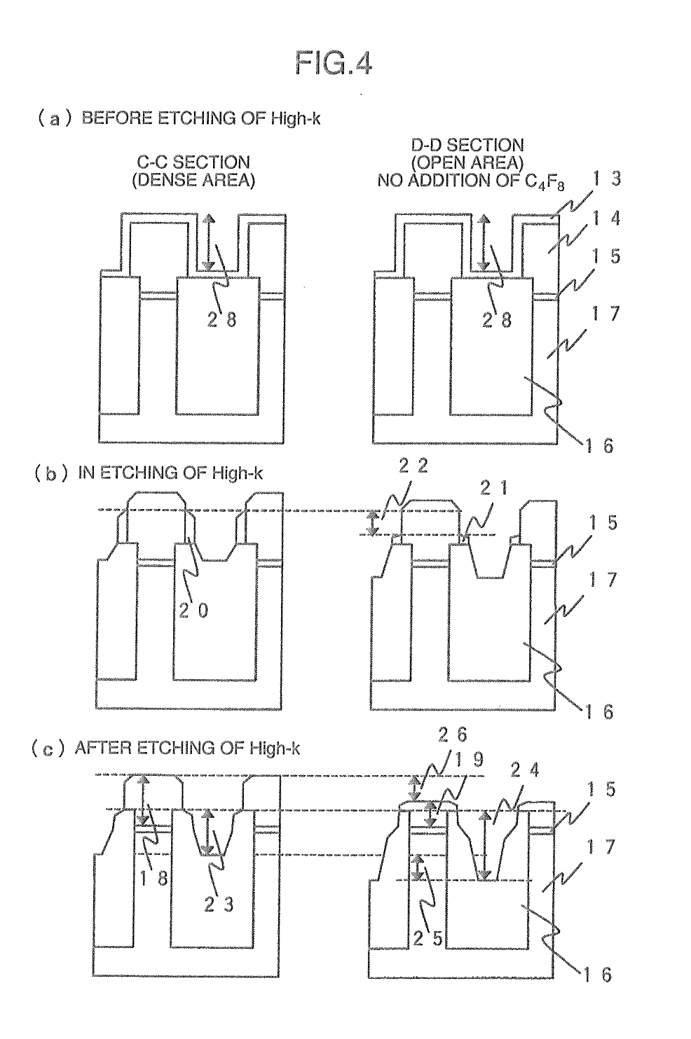

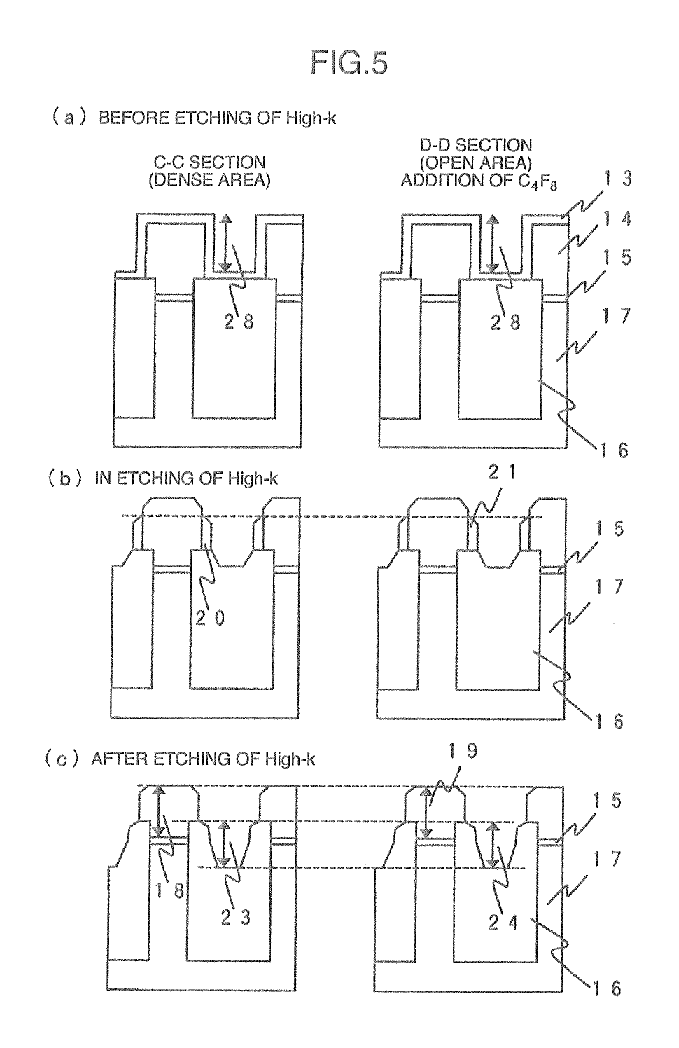

FIGS. 4A to 4C are views showing progress states of etching of a C-C section serving as a dense pattern area and a D-D section serving as open pattern area in FIGS. 3A and 3B when C₄F₈ is not added. With reference to FIGS. 4A to 4C, FIGS. 5A to 5C show progress states of etching when C₄F₈ is added.

When C₄F₈ is not added as shown in FIG. 4A, the High-k film 21 at the open area is etched at a rate lower than that of the High-k film 20 at the dense area to generate a remaining film difference 22 in a vertical direction as shown in FIG. 4B. When the High-k film 20 at the dense area is completely removed, the High-k film 21 at the open area is removed earlier than that at the dense area. As a result, as shown in FIG. 4C, etching time for the polysilicon underlayer at the open area when Al₂O₃ serving as the High-k film is not present is longer than that at the dense area, so that an etching reaction of polysilicon easily progresses. The polysilicon at the open area is etched, so that profile difference 26 occurs.

On the other hand, when C₄F₈ shown in FIG. 5 is added, a deposition including CₓF_{y} is formed on the High-k film surface to act in a direction to disturb the progress of etching. However, since a deposition rate is higher in the open area than in the dense area, the profile difference of the High-k film is improved. In this manner, as shown in FIG. 5B, etching at the open area on the right view progresses at a state that a difference in profile between the dense area on the left view and the open area on the right view is small. Thereby, as shown in FIG. 5C, etching being free from a difference in profile at the dense pattern area and the open pattern area can be performed. In this case, since a fluorocarbon gas (C₄F₈) having a high carbon ratio is added, a selectivity to polysilicon is not lowered without causing C₄F₈ itself to etch the polysilicon underlayer.

Furthermore, in the addition of C₄F₈, as shown in FIG. 5C, the silicon oxide film of the isolation trench 16 made of the same oxide as that of the, high-k film is etched without a difference in pattern density, which allows reduction of a profile difference 25 between the dense area and the open area of the isolation trench as shown in FIG. 4C.

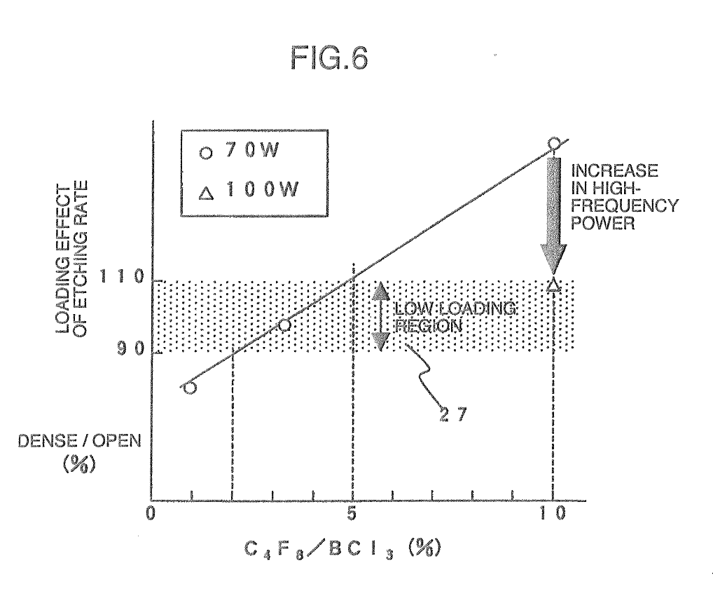

FIG. 6 is a graph showing a loading effect of etching rates of the High-k film when flow rates of the C₄F₈ gas are changed. This graph shows a flow-rate ratio of a BCl₃ gas and a C₄F₈ gas serving as etching gases. When an Ar flow rate, a BCl₃ flow rate, and a high-frequency power are 60 ccm, 60 ccm, and 70 W, respectively, a low loading effect of the etching rates is obtained when a flow-rate ratio of BCl₃ to C₄F₈ ranges 2% to 5%. In this case, in a low loading region 27 shown in FIG. 6, a ratio of an etching rate at the dense area to an etching rate at the open area is set within the range of 90% to 110%.

When the flow-rate ratio of C₄F₈ is 10%, an negative microloading phenomenon where the etching rate at the dense area is higher than the etching rate at the open area occurs. However, in this case, the high-frequency power is changed into 100 W, a preferable loading can be obtained. Similarly, when the flow-rate ratio is 1%, the high-frequency power is decreased to make it possible to obtain a preferable loading.

As described above, the high-frequency power is appropriately set to make it possible to adjust a profile difference on etching rates of the High-k film. However, when the high-frequency power is excessively increased, etching of the polysilicon underlayer cannot be suppressed. For this reason, a flow-rate ratio of C₄F₈ to BCl₃ is desirably set within the range of 1% to 10%, more preferably, within the range of 2% to 5%.

In the embodiment, Al₂O₃ is exemplified as the High-k film. However, the present invention can also be applied to etching of a High-k film made of AlₓO_{y}N_{z} (x=1 to 3, y=1 to 5, z=0 to 5), ZrₓO_{y}N_{z} (x=1 to 3, y=1 to 5, z=0 to 5), AlᵥHf_{w}SiₓO_{y}N_{z} (v=0 to 3, w=0 to 3, x=0 to 3, y=1 to 5, z=0 to 5), TaₓO_{y}N_{z} (x=1 to 3, y=1 to 5, z=0 to 5), and the like.

Also, C₄F₈ is used as an additive gas. When a fluorocarbon gas having a high carbon ratio such as a C₂F₄ gas, a C₃F₈ gas, a C₅F₈ gas or a C₄F₆ gas in which etching of polysilicon does not easily progress is used, a loading effect can be reduced by optimizing a flow rate of the additive gas and a high-frequency power applied to the electrode. For this reason, the present invention can be applied to not only the C₄F₈ gas but also the above fluorocarbon gases.

In the embodiment, the process of manufacturing a gate electrode of NAND Flash device are exemplified. However, the present invention can be applied to not only this process but also to etching or the like of a High-k film in manufacture of a SANOS (Silicon Aluminum-Oxide Nitride Oxide Silicon) type Flash device with an etching process for a metal oxide film such as an Al₂O₃ film. In addition, the process in manufacturing the gate electrode of the NAND Flash device is not limited to the embodiment. The materials or processing methods used in the hard mask, the tungsten silicide film, the polysilicon film, and the gate oxide film are not limited to the embodiment.

Furthermore, in the embodiment, the explanation is made on the assumption that the microwave ECR plasma etching apparatus is used. However, a plasma source except for the microwave ECR plasma etching apparatus can be used without any problem. Therefore, the present invention can be applied to a dielectric plasma apparatus or a parallel plate plasma apparatus.

It should be further understood by those skilled in the art that although the foregoing description has been made on embodiments of the invention, the invention is not limited thereto and various changes and modifications may be made without departing from the spirit of the invention and the scope of the appended claims.

### Advantages of the Invention

According to the present invention, a metal oxide film serving as a High-k film can be etched with etching characteristics having a small etching rate difference and a small profile difference between the open area and dense area while keeping a high selectivity to a polysilicon underlying film.

1. A dry etching method of a High-k film, comprising:
etching a metal oxide film, the metal oxide film having a metal bonded to oxygen; and
reducing an etching rate difference between an open area and a dense area of a control gate pattern, as compared to the etching rate difference between said open area and said dense area when using a gas mixture of Ar and BCl₃, by using a gas mixture of Ar, BCl₃ and one or more gasses selected from the group consisting of C₄F₈ and C₅F₈;
wherein, in the gas mixture, a flow-rate ratio of said one or more gasses selected from the group consisting of C₄F₈ and C₅F₈ to the BCl₃ gas ranges from 2% to 5%.

2. The dry etching method of a High-k film according to claim 1, wherein a metal of the metal oxide of the metal oxide film includes one or more metals selected from the group consisting of Al, Hf, Zr, Ta and Si.

3. The dry etching method of a High-k film according to claim 1, wherein the metal oxide film is constituted by a stacked film made of one or more selected from the group consisting of Al₂O₃, HfO₂, ZrO₂, AlHfO and Ta₂O₅.

4. A dry etching method of a High-k film, comprising:
etching a metal oxide film, the metal oxide film having a metal bonded to oxygen, while maintaining a selectivity for the metal oxide film relative to a polysilicon film forming a control gate, using a gas mixture of Ar, BCl₃ and adding one or more gasses selected from the group consisting of C₄F₈ and C₅F₈.

5. A dry etching method of a High-k film, comprising:
etching a metal oxide film, the metal oxide film having a metal bonded to oxygen; and
reducing an etching rate difference between an open area and a dense area of a control gate pattern, as compared to the etching rate difference between said open area and said dense area when using a gas mixture of Ar and BCl₃, by using a gas mixture of Ar, BCl₃ and one or more gasses selected from the group consisting of C₄F₈, C₅F₈ and C₄F₆,
wherein, in the gas mixture, a flow-rate ratio of said one or more gasses selected from the group consisting of C₄F₈, C₅F₈ and C₄F₆ to the BCl₃ gas ranges from 2% to 5%.

6. The dry etching method of a High-k film according to claim 5, wherein a metal of the metal oxide of the metal oxide film includes one or more metals selected from the group consisting of Al, Hf, Zr, Ta and Si.

7. The dry etching method of a High-k film according to claim 5, wherein the metal oxide film is constituted by a stacked film made of one or more selected from the group consisting of Al₂O₃, HfO₂, ZrO₂, AlHfO and Ta₂O₅.

8. The dry etching method of a High-k film according to claim 5, wherein said reducing is performed while maintaining a selectivity between etching the High-k film and etching the control gate pattern.
